(19) United States
(12) Patent Application Publication
(10) Pub. No.: US 2016/0181430 A1
(43) Pub. Date: Jun. 23, 2016

(54) IGZO Devices with Metallic Contacts and Methods for Forming the Same

(71) Applicant: Intermolecular Inc., San Jose, CA (US)

(72) Inventor: Khaled Ahmed, Anaheim, CA (US)

(21) Appl. No.: 14/575,687

(22) Filed: Dec. 18, 2014

(51) Int. Cl. H01L 29/786; H01L 29/24; H01L 29/423; H01L 23/532; H01L 21/441; H01L 29/45; H01L 21/768; H01L 27/12; H01L 29/66; H01L 21/02

(52) U.S. Cl. CPC H01L 29/7869; H01L 29/66969; H01L 29/24; H01L 29/42356; H01L 21/02565; H01L 21/441; H01L 29/45; H01L 21/768; H01L 27/124; H01L 23/53228

(57) ABSTRACT

Embodiments described herein provide indium-gallium-zinc oxide (IGZO) devices, such as IGZO thin-film transistors (TFTs), and methods for forming such devices. A substrate is provided. A gate electrode is formed above the substrate. A gate dielectric layer is formed above the gate electrode. An IGZO channel layer is formed above the gate dielectric layer. The IGZO channel layer includes crystalline IGZO. An electrode is formed above the IGZO channel layer. The electrode comprises titanium, aluminum, and nitrogen.

### TECHNICAL FIELD

The present invention relates to indium-gallium-zinc oxide (IGZO) devices.

More particularly, this invention relates to methods for forming IGZO devices, such as thin-film transistors (TFTs), with metallic contacts.

### BACKGROUND

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications. IGZO devices typically utilize amorphous IGZO (a-IGZO).

Recent developments in the field suggest that the use of crystalline IGZO may provide improved electrical and chemical stability. However, the use of crystalline IGZO may inhibit the performance of the device to relatively high contact resistivity with the source and drain electrodes, which are often made of titanium and/or molybdenum. The materials (e.g., titanium and molybdenum) also often do not provide a suitable barrier between the IGZO and the material(s) used to form the interconnects above the source and drain electrodes.

As a result, material from the interconnects (e.g., copper) may diffuse through the electrodes into the IGZO. This may particularly be an issue during annealing processes, and may degrade the performance of the devices.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with an indium-gallium-zinc oxide (IGZO) layer formed above the gate dielectric layer.

FIG. 4 is a cross-sectional view of the substrate of FIG. 3 with an IGZO channel layer formed above the gate dielectric layer.

FIG. 5 is a cross-sectional view of the substrate of FIG. 4 with an electrode layer formed above the IGZO channel layer.

FIG. 6 is a cross-sectional view of the substrate of FIG. 5 with source and drain electrodes formed above the IGZO channel layer.

FIG. 7 is a cross-sectional view of the substrate of FIG. 6 with a passivation layer formed above the source and drain electrodes.

FIG. 8 is a cross-sectional view of the substrate of FIG. 7 with interconnects formed through the passivation layer.

FIG. 9 is a simplified cross-sectional diagram of a physical vapor deposition (PVD) tool according to some embodiments.

FIG. 10 is a flow chart illustrating a method for forming IGZO devices according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide indium-gallium-zinc oxide (IGZO) devices, such as IGZO thin-film transistors (TFTs), with high channel mobility and ultra-low source/drain contact resistivity. This is accomplished using, for example, a crystalline IGZO (e.g., more than 30% crystalline by volume) channel layer in the device, along with source/drain electrode made of titanium, aluminum, and nitrogen, such as titanium-aluminum nitride. In particular, in some embodiments, the electrodes are made of titanium-aluminum nitride that includes less than 30% nitrogen by weight. In some embodiments, interconnects are formed above the electrodes. The interconnects may include copper.

The IGZO devices may benefit from the low work function of the titanium-aluminum nitride in the electrodes, as well as the ability of the titanium-aluminum nitride to function as a barrier to protect the IGZO from copper diffusion from the interconnects, particularly during the annealing of the device (e.g., 200-300° C.).

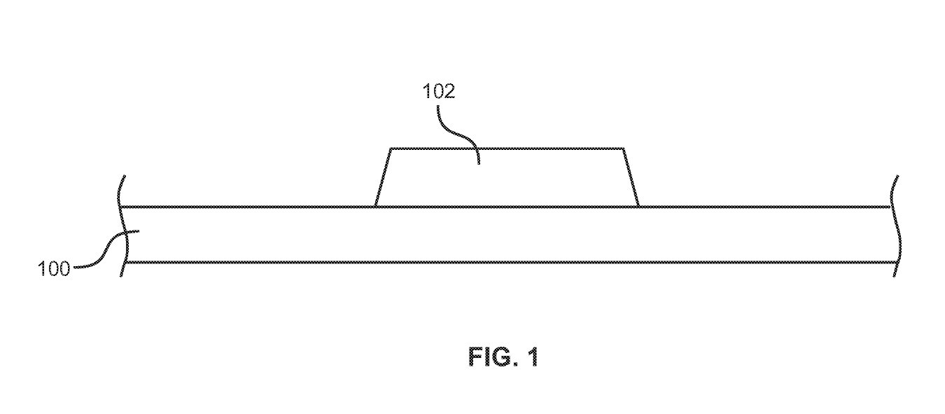

FIGS. 1-8 illustrate a method for forming an IGZO TFT (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between about 0.01 centimeters (cm) and about 0.5 cm. Although only a portion of the substrate 100 is shown, it should be understood that the substrate 100 may have a width of, for example, between about 5.0 cm and about 4.0 meters (m). Although not shown, in some embodiments, the substrate 100 may have a dielectric layer (e.g., silicon oxide) formed above an upper surface thereof. In such embodiments, the components described below may be formed above the dielectric layer. Also, in some embodiments, the substrate 100 is at least partially made of a of a semiconductor material (e.g., silicon, germanium, gallium arsenide, etc.). For example, in some embodiments, the substrate includes glass with a layer of semiconductor material formed thereon.

Still referring to FIG. 1, a gate electrode 102 is formed above the substrate 100. In some embodiments, the gate electrode 102 is made of a conductive material, such as copper, silver, aluminum, manganese, molybdenum, or a combination thereof. The gate electrode may have a thickness of, for example, between about 20 nanometers (nm) and about 500 nm. Although not shown, it should be understood that in some embodiments, a seed layer (e.g., a copper alloy) is formed between the substrate 100 and the gate electrode 102.

It should be understood that the various components above the substrate, such as the gate electrode 102 and those described below, are formed using processing techniques suitable for the particular materials being deposited, such as physical vapor deposition (PVD) (e.g., co-sputtering), chemical vapor deposition (CVD), plasma-enhanced CVD (PECVD), atomic layer deposition (ALD), electroplating, etc. Furthermore, although not specifically shown in the figures, it should be understood that the various components formed above the substrate 100, such as the gate electrode 102, may be sized and shaped using a photolithography process and an etching process, as is commonly understood, such that the components are formed above selected regions of the substrate 100.

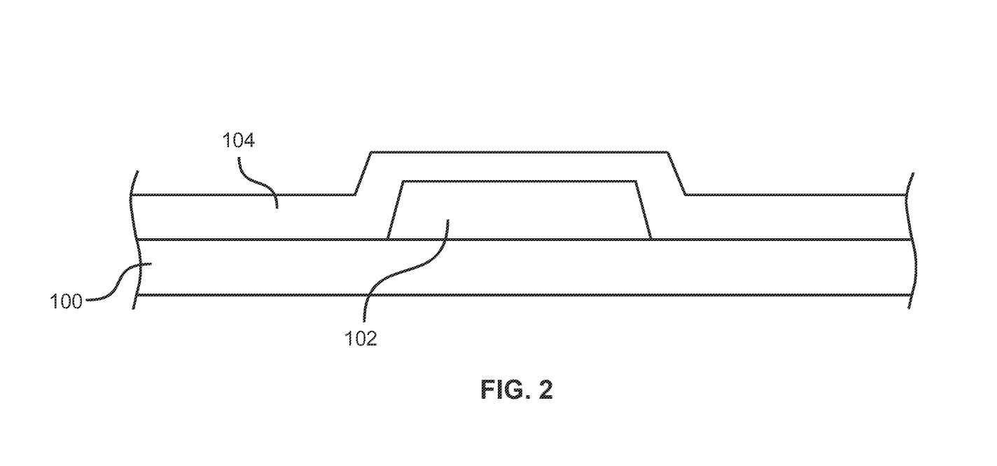

Referring to FIG. 2, a gate dielectric layer 104 is then formed above the gate electrode 102 and the exposed portions of the substrate 100. The gate dielectric layer 104 may be made of, for example, silicon oxide, silicon nitride, or a high-k dielectric (e.g., having a dielectric constant greater than 3.9), such as zirconium oxide, hafnium oxide, aluminum oxide, or titanium oxide. In some embodiments, the gate dielectric layer 104 has a thickness of, for example, between about 10 nm and about 500 nm. The gate dielectric layer 104 may be formed using, for example, PVD, CVD, PECVD, or ALD.

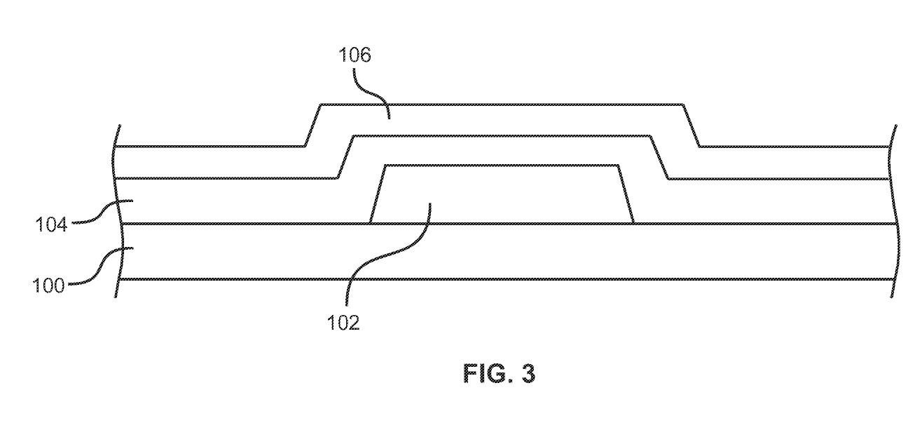

Referring now to FIG. 3, an IGZO layer 106 is then formed above the gate dielectric layer 104. The IGZO layer 106 may be made of IGZO in which a ratio of the respective elements (or the atomic ratio) is, for example, 1:1:1:1-3. In some embodiments, the IGZO within the IGZO layer 106 is deposited as amorphous IGZO (a-IGZO). However, in some embodiments, the IGZO is formed or deposited using processing conditions to enhance the crystalline structure thereof. In some embodiments, the IGZO layer 106 is formed using PVD. The IGZO may be deposited from a single target that includes indium, gallium, and zinc (e.g., an indium-gallium-zinc alloy target or an IGZO target), but two or more targets may also used (e.g., co-sputtering with an indium-zinc target and a gallium target). The IGZO layer 106 may have a thickness of, for example, between about 30 nm and about 100 nm, such as about 50 nm. It should be noted that in at least some embodiments, the IGZO layer 106 (and the IGZO channel layer described below) and the gate dielectric layer 104 are made of different materials.

Although not specifically shown, in some embodiments, the IGZO layer 106 (and the other components shown in FIG. 3) may then undergo an annealing process.

In some embodiments, the annealing process includes a relatively low temperature (e.g., less than about 600° C., preferably less than about 450° C.) heating process in, for example, an ambient gaseous environment (e.g., nitrogen, oxygen, or ambient/air) to (further) enhance the crystalline structure of the IGZO. The heating process may occur for between about 1 minute and about 200 minutes. After the annealing (or heating) process, the IGZO layer 106 may (substantially) include crystalline IGZO (c-IGZO). As used herein a “crystalline” material (e.g., c-IGZO) may be considered to be one that is more than 30% crystalline by volume, as determined by a technique such as X-ray Diffraction (XRD). In some embodiments, the c-IGZO is c-axis aligned crystal (CAAC) IGZO, as is commonly understood.

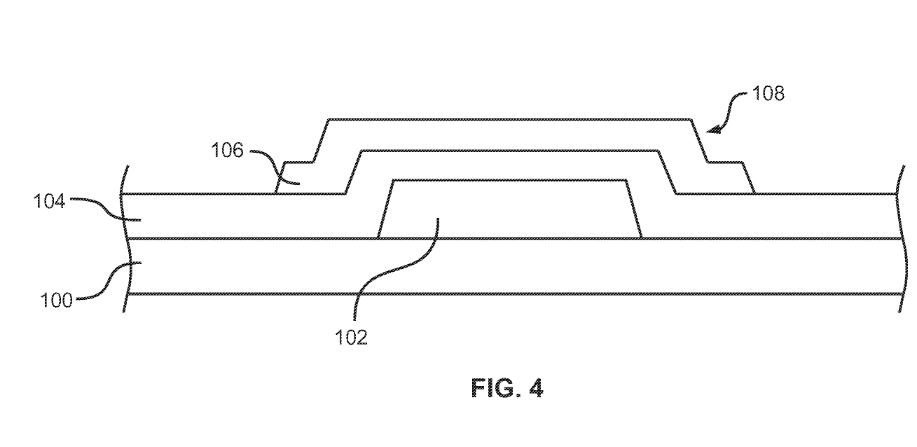

Referring to FIG. 4, after the annealing process, the IGZO layer 106 is patterned (e.g., etched) to form an IGZO channel (or channel layer) 108 (e.g., made of substantially c-IGZO) above the gate dielectric layer 104. In some embodiments, the IGZO channel 108 is formed above the gate electrode 102 such that the ends of the IGZO channel 108 extend beyond the ends of the gate electrode 102.

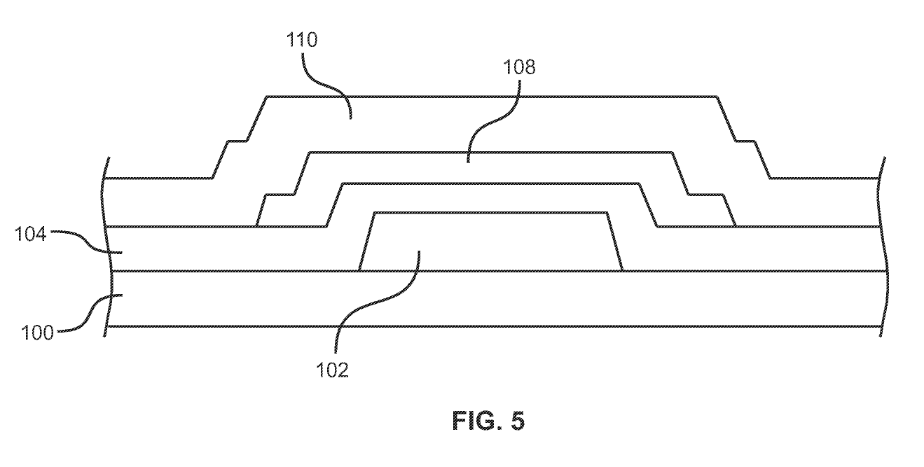

As shown in FIG. 5, an electrode layer 110 is then formed above the IGZO channel 108, as well as the exposed portions of the gate dielectric layer 104. In some embodiments, the electrode layer 110 includes (or is made of) titanium, aluminum, and nitrogen. In some embodiments, the electrode layer 110 is made of (or substantially made of) titanium-aluminum nitride. The titanium-aluminum nitride may include less than 30% nitrogen by weight. In some embodiments, the material of the electrode layer 110 (e.g., titanium-aluminum nitride) is formed (or deposited) directly on the IGZO channel 108. That is, in some embodiments, no barrier layer is formed between the material of the electrode layer 110 and the IGZO channel 108, and the electrode layer 110 is made of a single material (e.g., titanium-aluminum nitride), as opposed to multiple sub-layers of different materials. The electrode layer 110 may be formed using, for example, PVD and have a thickness of, for example, between about 20 nm and about 500 nm.

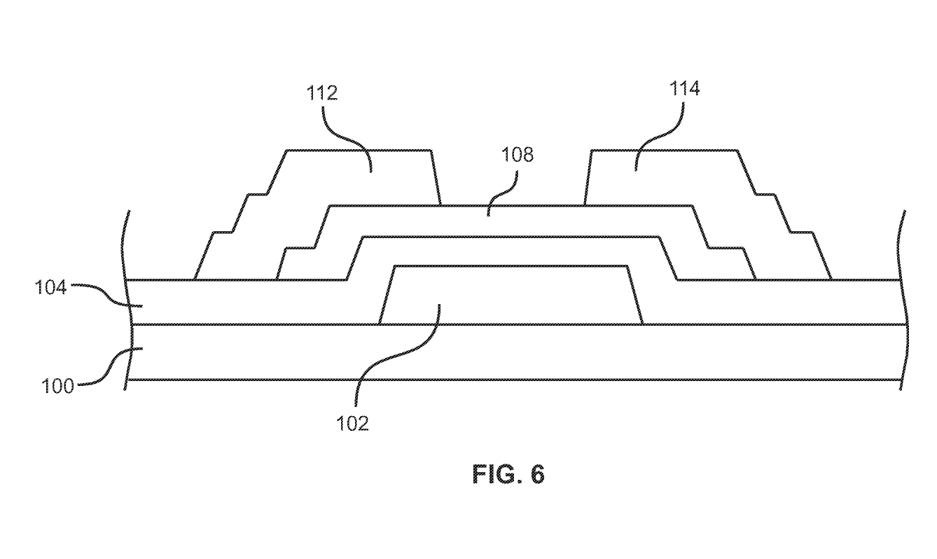

Referring now to FIG. 6, a source electrode (or region) 112 and a drain electrode 114 are then formed above the IGZO channel 108 by, for example, patterning (e.g., etching) the electrode layer 110 (i.e., and are thus made of the same material(s) as the electrode layer 110, such as titanium-aluminum nitride). As shown, the source electrode 112 and the drain electrode 114 lie on opposing sides of, and partially overlap the ends of, the IGZO channel 108. As will be appreciated by one skilled in the art, the source electrode 112 and the drain electrode 114 may be defined as shown in FIG. 6 using a “back-channel etch” (BCE) process to, for example, form the gap between the source electrode 112 and the drain electrode 114, which is vertically aligned with the gate electrode 102. However, in some embodiments, an etch-stop layer, as is commonly understood, may be formed above the IGZO channel layer 110 to facilitate the defining of the source electrode 112 and the drain electrode 114 (e.g., by protecting the IGZO during the etch process).

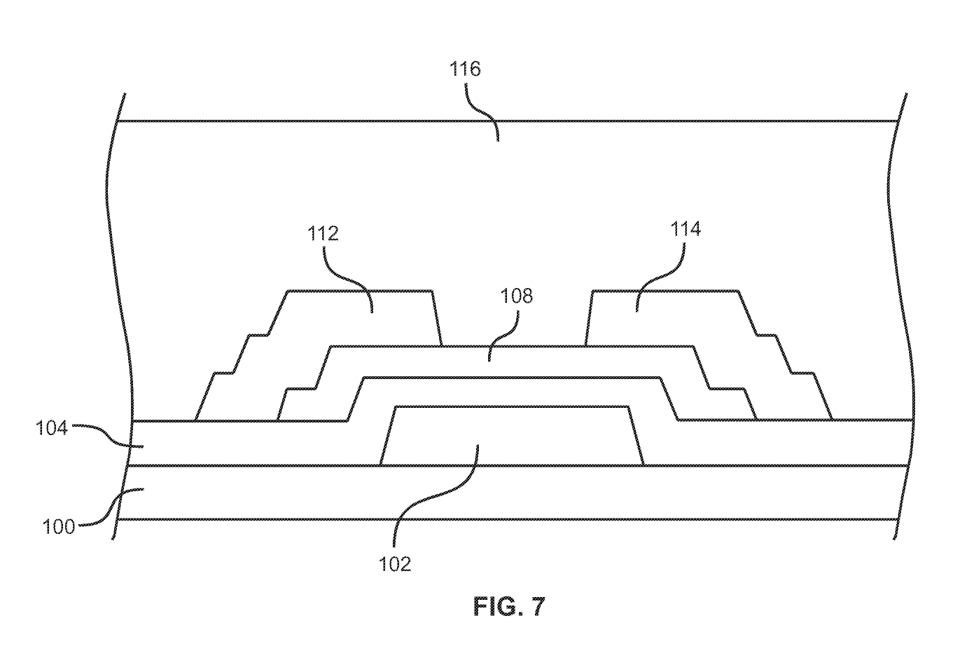

Referring to FIG. 7, a passivation layer 116 is then formed above the source electrode 112, the drain electrode 114, and the exposed portions of the gate dielectric layer 104 and the IGZO channel 108. In some embodiments, the passivation layer 116 is made of silicon oxide, silicon nitride, aluminum oxide, aluminum nitride, or a combination thereof and has a thickness of, for example, between about 0.1 micrometers (μm) and about 1.5 μm.

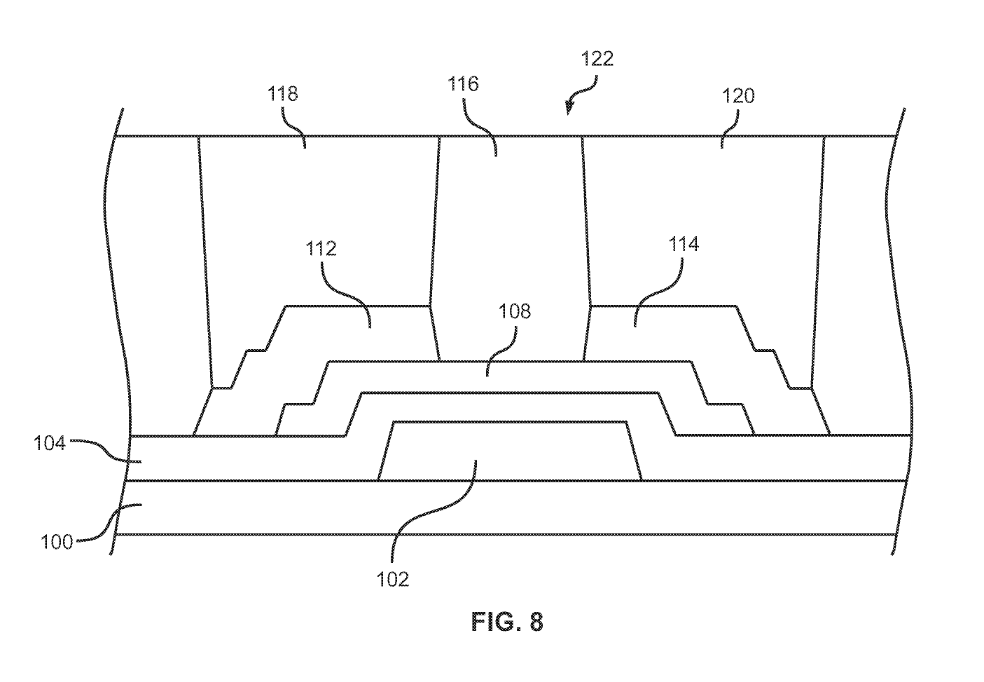

As shown in FIG. 8, interconnects 118 and 120 are then respectively formed through the passivation layer 116 above the source electrode 112 and the drain electrode 114. Although not specifically shown, the interconnects 118 and 120 may be formed by forming vias or openings through the passivation layer 116 and then filling the openings with a conductive material. In some embodiments, the interconnects 118 and 120 include (or are made of) copper and are formed using an electroplating process, as is commonly understood. In some embodiments, the material of the interconnects 118 and 120 (e.g., copper) is formed (or deposited) directly on the source electrode 112 and the drain electrode 114 (i.e., no barrier layer is formed between the interconnects and the source/drain electrodes).

The formation of the interconnects 118 and 120 may substantially complete the formation of an IGZO device 122, such as an inverted, staggered bottom-gate IGZO TFT. Although not shown, in some embodiments, after the formation of the interconnects 118 and 120, the IGZO device 122 may undergo a final annealing (or heating) process. The heating process may take place at a temperature of, for example, between about 200° C. and about 300° C.

It should be understood that although only a single device 122 is shown as being formed on a particular portion of the substrate 100 in FIGS. 1-8, the manufacturing processes described above may be simultaneously performed on multiple portions of the substrate 100 such that multiple devices 122 are simultaneously formed, as is commonly understood. Additionally, although not shown, in some embodiments intended for use in display applications, pixel electrodes may also be formed above the substrate 100 during the formation of the IGZO device(s) 122. The pixel electrodes may be made of a transparent conductive material, such as indium-tin oxide (ITO).

The IGZO devices described above may have high channel mobility and ultra-low source/drain contact resistivity due to, for example, the use of crystalline IGZO in the channel layer, along with source/drain electrode made of titanium, aluminum, and nitrogen, such as titanium-aluminum nitride. The IGZO devices may also benefit from the low work function (e.g., 4.2 eV) of the titanium-aluminum nitride in the electrodes, as well as the ability of the titanium-aluminum nitride to function as a barrier to protect the IGZO from copper diffusion from the interconnects, particularly during the final annealing of the device. In should be noted that in at least some embodiments, no separate barrier layers are formed between the interconnects and the source/drain electrodes and between the source/drain electrodes and the IGZO channel. As a result, the manufacturing of the devices may be simplified, thus reducing costs.

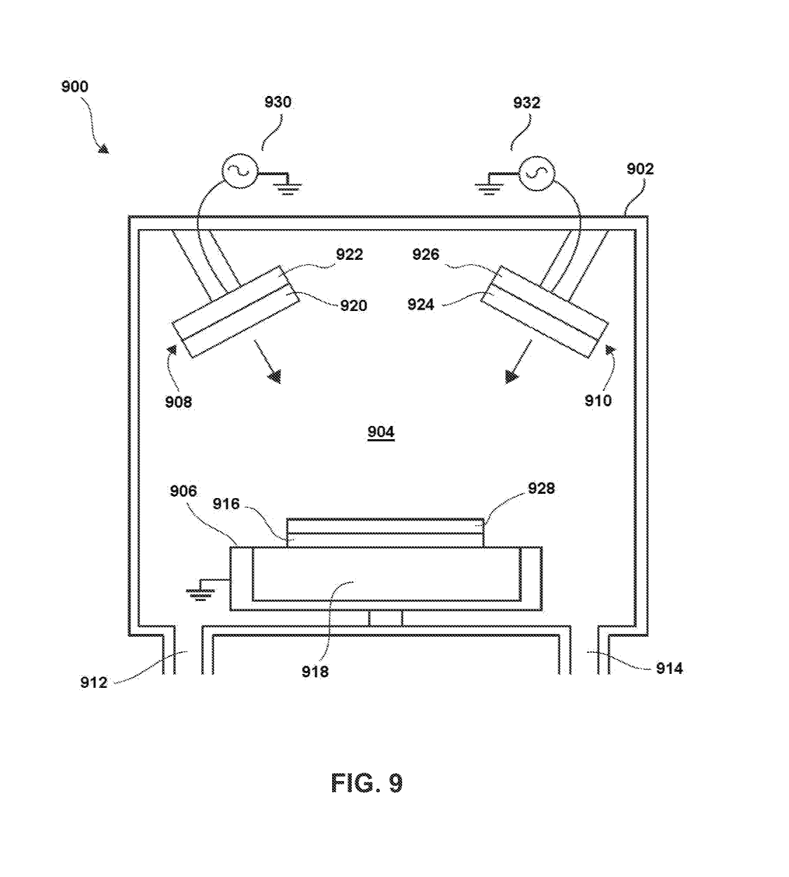

FIG. 9 provides a simplified illustration of a physical vapor deposition (PVD) tool (and/or system) 900 which may be used, in some embodiments, to form some of the components of the IGZO devices described above. The PVD tool 900 shown in FIG. 9 includes a housing 902 that defines, or encloses, a processing chamber 904, a substrate support 906, a first target assembly 908, and a second target assembly 910.

The housing 902 includes a gas inlet 912 and a gas outlet 914 near a lower region thereof on opposing sides of the substrate support 906. The substrate support 906 is positioned near the lower region of the housing 902 and in configured to support a substrate 916. The substrate 916 may be a round substrate having a diameter of, for example, about 200 mm or about 300 mm. In other embodiments (such as in a manufacturing environment), the substrate 916 may have other shapes, such as square or rectangular, and may be significantly larger (e.g., about 0.5 m to about 4 m across). The substrate support 906 includes a support electrode 918 and is held at ground potential during processing, as indicated.

The first and second target assemblies (or process heads) 908 and 910 are suspended from an upper region of the housing 902 within the processing chamber 904. The first target assembly 908 includes a first target 920 and a first target electrode 922, and the second target assembly 910 includes a second target 924 and a second target electrode 926. As shown, the first target 920 and the second target 924 are oriented or directed towards the substrate 916. As is commonly understood, the first target 920 and the second target 924 include one or more materials that are to be used to deposit a layer of material 928 on the upper surface of the substrate 916.

The materials used in the targets 920 and 924 may, for example, include indium, gallium, zinc, tin, silicon, silver, aluminum, manganese, molybdenum, zirconium, hathium, titanium, copper, or any combination thereof (i.e., a single target may be made of an alloy of several metals). In some embodiments, the materials used in the targets may include oxygen, nitrogen, or a combination of oxygen and nitrogen in order to form oxides, nitrides, and oxynitrides. Further, although only two targets 920 and 924 are shown, additional targets may be used.

The PVD tool 900 also includes a first power supply 930 coupled to the first target electrode 922 and a second power supply 932 coupled to the second target electrode 924. As is commonly understood, in some embodiments, the power supplies 930 and 932 pulse direct current (DC) power to the respective electrodes, causing material to be, at least in some embodiments, simultaneously sputtered (i.e., co-sputtered) from the first and second targets 920 and 924. In some embodiments, the power is alternating current (AC) to assist in directing the ejected material towards the substrate 916.

During sputtering, inert gases (or a plasma species), such as argon or krypton, may be introduced into the processing chamber 904 through the gas inlet 912, while a vacuum is applied to the gas outlet 914. The inert gas(es) may be used to impact the targets 920 and 924 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 9, the PVD tool 900 may also include a control system having, for example, a processor and a memory, which is in operable communication with the other components shown in FIG. 9 and configured to control the operation thereof in order to perform the methods described herein.

Although the PVD tool 900 shown in FIG. 9 includes a stationary substrate support 906, it should be understood that in a manufacturing environment, the substrate 916 may be in motion (e.g., an in-line configuration) during the formation of various layers described herein.

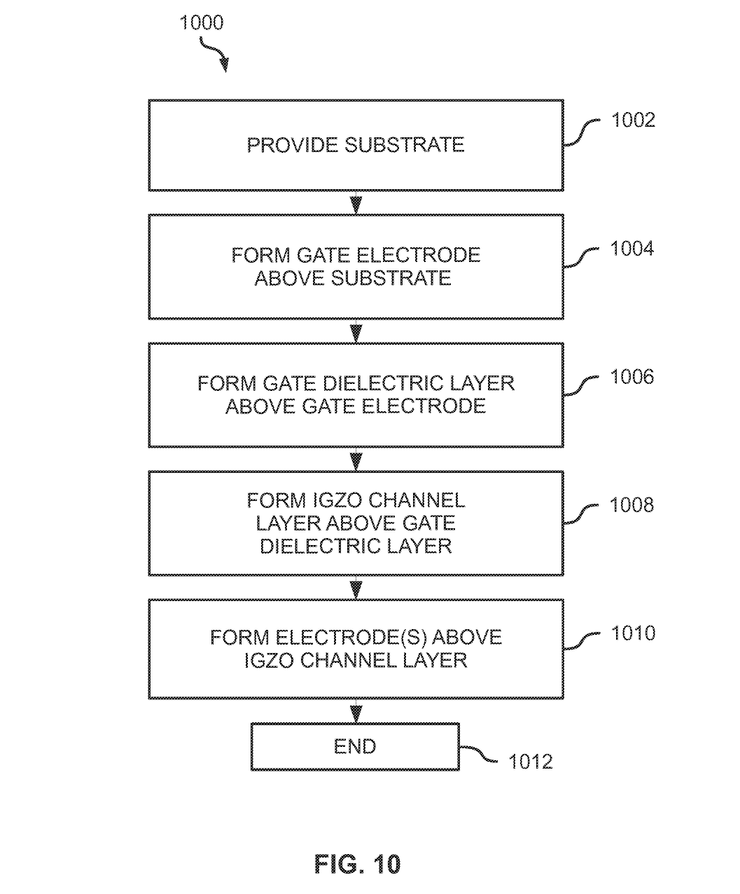

FIG. 10 illustrates a method 1000 for forming an IGZO device, such as an IGZO TFT, according to some embodiments. At block 1002, the method 1000 begins with a substrate being provided. As described above, in some embodiments, the substrate includes glass, a semiconductor material, or a combination thereof.

At block 1004, a gate electrode is formed above the substrate. The gate electrode may be made of a conductive material, such as copper, silver, aluminum, manganese, molybdenum, or a combination thereof.

At block 1006, a gate dielectric layer is formed above the gate electrode. The gate dielectric layer may be made of, for example, silicon oxide, silicon nitride, or a high-k dielectric (e.g., having a dielectric constant greater than 3.9), such as zirconium oxide, hafnium oxide, aluminum oxide, or titanium oxide. In some embodiments, the gate dielectric layer has a thickness of, for example, between about 10 nm and about 500 nm. The gate dielectric layer may be formed using, for example, PVD, CVD, PECVD, or ALD.

At block 1008, an IGZO channel layer is formed above the gate dielectric layer. In some embodiments, the IGZO within the IGZO layer is deposited as a-IGZO. However, in some embodiments, the IGZO is formed or deposited using processing conditions to enhance the crystalline structure thereof.

At block 1010, one or more electrodes (e.g., source and drain electrodes) are formed above the IGZO channel layer. The electrode(s) may made of, for example, titanium, aluminum, and nitrogen. In some embodiments, the electrode(s) is made of (or substantially made of) titanium-aluminum nitride. The titanium-aluminum nitride may include less than 30% nitrogen by weight.

Although not shown, in some embodiments, the method 1000 includes the formation of additional components of an IGZO device, such as a passivation layer and interconnects (e.g.,, made of copper) formed through the passivation layer, as well as additional processing steps, such as an annealing process. At block 1012, the method 1000 ends.

Thus, in some embodiments, methods for forming an IGZO device are provided. A substrate is provided. A gate electrode is formed above the substrate. A gate dielectric layer is formed above the gate electrode. An IGZO channel layer is formed above the gate dielectric layer. The IGZO channel layer includes crystalline IGZO. An electrode is formed above the IGZO channel layer. The electrode comprises titanium, aluminum, and nitrogen.

In some embodiments, methods for forming an IGZO device are provided. A substrate is provided. A gate electrode is formed above the substrate. A gate dielectric layer is formed above the gate electrode. An IGZO channel layer is formed above the gate dielectric layer. The material of the IGZO channel layer is more than 30% crystalline by volume. A source electrode and a drain electrode are formed above the IGZO channel layer. Each of the source electrode and the drain electrode includes titanium-aluminum nitride.

In some embodiments, IGZO devices are provided. Each IGZO device includes a substrate. A gate electrode is formed above the substrate. A gate dielectric layer is formed above the gate electrode. An IGZO channel layer is formed above the gate dielectric layer. The IGZO channel layer includes crystalline IGZO. An electrode is formed above the IGZO channel layer. The electrode includes titanium, aluminum, and nitrogen.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for forming an indium-gallium-zinc oxide (IGZO) device, the method comprising:
providing a substrate;
forming a gate electrode above the substrate;
forming a gate dielectric layer above the gate electrode;
forming an IGZO channel layer above the gate dielectric layer, wherein the IGZO channel layer comprises crystalline IGZO;
forming an electrode above the IGZO channel layer, wherein the electrode comprises titanium-aluminum nitride; and
forming an interconnect above the electrode, wherein the interconnect comprises copper formed directly on the titanium-aluminum nitride of the electrode.

2. The method of claim 1, wherein the electrode consists of titanium-aluminum nitride.

3. The method of claim 2, wherein the titanium-aluminum nitride comprises less than 30% nitrogen by weight.

4. The method of claim 3, wherein the the electrode is formed directly on the crystalline IGZO of the IGZO channel layer.

5. The method of claim 4, further comprising forming an interconnect above the electrode, wherein the interconnect is electrically connected to the electrode wherein the gate electrode comprises copper, silver, aluminum, manganese, molybdenum, or a combination thereof.

6. The method of claim 2, wherein the interconnect consists of copper.

7. The method of claim 6, wherein the copper of the interconnect is formed directly on the titanium-aluminum nitride of the electrode gate dielectric layer comprises silicon oxide, silicon nitride, zirconium oxide, hafnium oxide, aluminum oxide, or titanium oxide.

8. The method of claim 2, wherein the crystalline IGZO of the IGZO channel layer is more than 30% crystalline by volume.

9. The method of claim 8, wherein a thickness of the IGZO channel layer is between about 30 nanometers (nm) and about 100 (nm).

10. The method of claim 9, wherein a thickness of the electrode is between about 20 nm and about 500 nm.

11. A method for forming an indium-gallium-zinc oxide (IGZO) device, the method comprising:
providing a substrate;
forming a gate electrode above the substrate;
forming a gate dielectric layer above the gate electrode;
forming an IGZO channel layer above the gate dielectric layer, wherein the material of the IGZO channel layer is more than 30% crystalline by volume;
forming a source electrode and a drain electrode above the IGZO channel layer, wherein each of the source electrode and the drain electrode comprises titanium-aluminum nitride; and
forming a first interconnect directly on the source electrode and a second interconnect directly on the drain electrode, wherein each of the first interconnect and the second interconnect consists of copper.

12. The method of claim 11, wherein the titanium-aluminum nitride comprises less than 30% nitrogen by weight.

13. The method of claim 12, wherein the source electrode and the drain electrode are formed directly on the IGZO channel layer.

14. The method of claim 13, wherein the gate electrode comprises copper, silver, aluminum, manganese, molybdenum, or a combination thereof.

15. The method of claim 14, wherein the first interconnect is formed directly on the source electrode, and the second interconnect is formed directly on the drain electrode.

16. An indium-gallium-zinc oxide (IGZO) device comprising:
a substrate;
a gate electrode formed above the substrate;
a gate dielectric layer formed above the gate electrode;
an IGZO channel layer formed above the gate dielectric layer, wherein the IGZO channel layer comprises crystalline IGZO;
an electrode formed above the IGZO channel layer, wherein the electrode comprises titanium-aluminum nitride; and
an interconnect formed above the electrode, wherein the interconnect comprises copper,
wherein the IGZO device does not comprise a barrier layer formed between the IGZO channel layer and the interconnect.

17. The IGZO device of claim 16, wherein the IGZO channel layer is more than 30% crystalline by volume.

18. The IGZO device of claim 17, wherein the electrode consists of titanium-aluminum nitride.

19. The IGZO device of claim 18, wherein the titanium-aluminum nitride comprises less than 30% nitrogen by weight.

20. The IGZO device of claim 19, wherein the interconnect is formed directly on the electrode, wherein the and consists of copper.
